(19) United States
(12) Patent Application Publication
(10) Pub. No.: US 2006/0066350 A1
(43) Pub. Date: Mar. 30, 2006

(54) Equalizing driver circuit and method of operating same

(76) Inventor: Fred F. Chen, San Francisco, CA (US)

Correspondence Address: HUNTON & WILLIAMS LLP/RAMBUS INC.;INTELLECTUAL PROPERTY DEPARTMENT, 1900 K STREET, N.W., SUITE 1200, WASHINGTON, DC, 20006-1109, US

(21) Appl. No.: 10/949,372

(22) Filed: Sep. 27, 2004

(51) Int. Cl. H03K 19/0175

(52) U.S. Cl. 326/82

(57) ABSTRACT

An equalizing driver circuit is disclosed. In one particular exemplary embodiment, the equalizing driver circuit may comprise dedicated driver circuitry having a first current source switchably coupled to an output node of the driver circuit, wherein the first current source is configured to selectively draw a variable quantity of current. The equalizing driver circuit may also comprise allocated driver circuitry having a second current source switchably coupled to the output node, wherein the second current source is configured to draw a fixed quantity of current.

### FIELD OF THE DISCLOSURE

The present disclosure relates generally to the field of high speed signaling.

### BACKGROUND OF THE DISCLOSURE

An output driver circuit with a drive strength which can be adjusted to compensate for channel effects such as, for example, inter-symbol interference (ISI) or inductive coupling between neighboring signal paths (i.e., crosstalk), is sometimes referred to as an equalizing output driver circuit, or more simply, as an equalizing driver circuit. Equalizing driver circuits are often used in high-speed signaling systems.

FIG. 1 illustrates ISI in a prior-art signaling system in which data is transmitted as a series of distinct signal levels. At time T1, a logic 0 signal is transmitted on a signal line by pulling the line up to level V_{H}. Subsequently, at time T2, a logic 1 is transmitted by pulling the line down to level V_{L}. Finally, at time T3, a logic 0 is transmitted again by pulling the signal line up to V_{H}.

Because the signal driving circuit has finite drive strength (i.e., finite ability to sink and source current), the voltage level of the signal line does not change instantaneously at time T2 or time T3, but rather exhibits a finite slew rate. Consequently, the ideal times for sampling (i.e., in a receiving circuit) the signals output at times T1, T2, and T3 occur at sample times S1, S3, and S3, respectively, after the signals have transitioned to a relative minimum or maximum level and before the signals begin transitioning to a next level. As shown in FIG. 1, “t” is the time required for the signals output at times T1, T2, and T3 to travel from the signal driving circuit to the receiving circuit for sampling at sample times S1, S2, and S3, respectively.

Referring to sample time S2 in particular, note that the level of the signal is affected not only by the logic 1 output at time T2, but also by the logic 0 output at time T1 which, due to the finite slew rate of the transmitter, limits the ability of the signal level to reach and settle at V_{L}. The signal at sample time S2 is also affected by the logic 0 transmitted at time T3 which limits the ability of the signal level to settle and hold at V_{L}. Thus, values transmitted before and after the signal transmitted at time T2 interfere with the level of the T2 signal at the receiver due to ISI.

FIG. 2 illustrates a prior-art output driver 100 in which ISI is reduced by dynamically increasing and decreasing the signal drive strength of the output driver 100 according to the relationship between past, present and future transmit data (TDATA). For example, if a logic 1 is to be transmitted (present data=1), but a logic 0 was transmitted previously, the drive strength of the output driver 100 is temporarily increased to achieve faster slew from the logic 0 to logic 1 signal levels, thereby reducing the ISI caused by the previous transmission. Similarly, if a logic 1 is to be transmitted followed by a logic 0, the drive strength of the output driver is temporarily increased to reduce the ISI caused by the subsequent transmission. Such dynamic adjustments to the drive strength of the output driver 100 are referred to as equalization operations.

The output driver 100 includes three sub-driver circuits formed by respective current-sinking drive transistors (109, 111, 113) and corresponding bias current sources (110, 112, 114). The sub-driver circuits drive future, present and past data values, /A, B, and /C, respectively (the ‘/’ symbol indicating complement), onto an output signal line 102 that is pulled up to a supply voltage through resistor, R. Flip-flops 105 and 107 are coupled in series to form a shift register for producing the present and past data values, B and /C, by shifting an incoming data signal, TDATA (i.e., /A), in response to a transmit clock signal, TCLK. Thus, during a given cycle of the transmit clock signal, /A represents a data value transmitted in a subsequent cycle, B represents a data value transmitted during a present clock cycle, and /C represents a data value transmitted during a previous clock cycle. The bias currents produced by current sources 110, 112, and 114 are 0.1I, 0.8I, and 0.1I, respectively, so that the present data value, when high, draws current 0.8I (i.e., by switching on transistor 111) to pull the output signal line 102 low, and the future and past values, when low, each draw current 0.1I (i.e., by switching on transistors 109 and 113, respectively) to pull the output signal line 102 low by incremental amounts.

FIG. 3 illustrates the effect of the future, present, and past data values on the total current drawn by the prior-art output driver 100 of FIG. 2. At time T1, the future, present, and past data values (i.e., A_{T1}, B_{T1}, and C_{T1}) are all zero so that, referring to FIG. 2, transistors 109 and 113 are switched on (i.e., due to the inversions of values A and C), and transistor 111 is switched off. Accordingly, the output driver 100 sinks a current of 0.2I to represent a steady-state logic 0 condition and the voltage level of output signal line 102 is pulled down slightly to a nominal, V_{H} level. At time T2, the values of A, B, and C are shifted such that C_{T2}=B_{T1}=0, B_{T2}=A_{T1}=0, and A_{T2}=1. In this state, the current drawn by the output driver 100 is reduced from 0.2I to 0.1I to counteract the ISI that would otherwise result from subsequent transmission of a logic 1 value at time T3.

At time T3, the values of A, B, and C are shifted again such that B_{T3}=A_{T2}=1, C_{T3}=B_{T2}=0, and A_{T3}=1. Because B is high and C is low, the output driver 100 sinks a current of 0.9I (i.e., 0.8I via transistor 111 and 0.1I via transistor 113). This current level may be understood by viewing the 0.8I drawn by transistor 111 as being a nominal current needed to produce the present logic 1 value, plus a current 0.1I drawn by transistor 113 to counteract the ISI from the logic 0 transmitted during the preceding transmission interval.

At time, T4, the present, past and future values all transition high (i.e., A_{T4}=B_{T4}=C_{T4}=1), so that a current of 0.8I is drawn to represent the steady-state logic 1 condition.

Finally, at time T5, the present and past values remain at logic 1 (i.e., B_{T5}=C_{T5}=1), but the future value, A_{T5}, becomes a logic 0. Consequently, the current drawn by the output driver 100 increases from 0.8I to 0.9I to counteract the ISI from the subsequent logic 0 transmission.

Referring again to FIG. 2, signal equalization is achieved by the output driver 100 by driving the output signal line 102 with two additional sub-driver circuits (i.e., sub-driver circuits for past and future data). Because each sub-driver exhibits a parasitic capacitance, Cᵢ, the net affect of coupling additional sub-driver circuits to the output signal line 102 is to increase the total parasitic capacitance of the output driver 100 from Cᵢ to 3Cᵢ. This presents a significant problem in high-speed signaling systems, where the parasitic capacitance of the output driver tends to be a dominant, bandwidth-limiting capacitance of the signaling system. Additionally, transmission paths in high-speed signaling systems are often terminated by termination elements having impedances selected to match the impedance of the transmission paths (i.e., as shown in FIG. 2, R is chosen to match Z₀), thereby reducing undesired signal reflections. The increased parasitic capacitance of the equalizing driver circuit produces a mismatch between the effective termination impedance and the transmission path impedance, thereby increasing the level of signal reflections on the transmission path. Thus, it would be desirable to provide an equalizing driver circuit having reduced parasitic capacitance.

Also, systems that use multiple multiplexed data inputs in a segmented digital-to-analog converter (DAC) to implement analog addition (such as in equalization) can be subject to severe DAC rollover glitches if the weights of the data inputs to be summed are changed haphazardly. For example, this can occur in an equalizing driver circuit whose tap weights are constantly being adjusted to compensate for time varying conditions (e.g., temperature, etc.) while it is transmitting data. In this case, glitches in the equalizing driver circuit beyond the intended change can potentially cause additional timing/voltage noise resulting in bit errors of the data being transmitted.

In view of the foregoing, it would be desirable to provide an equalizing driver circuit which overcomes the above-described inadequacies and shortcomings.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 illustrates inter-symbol interference in a prior-art signaling system.

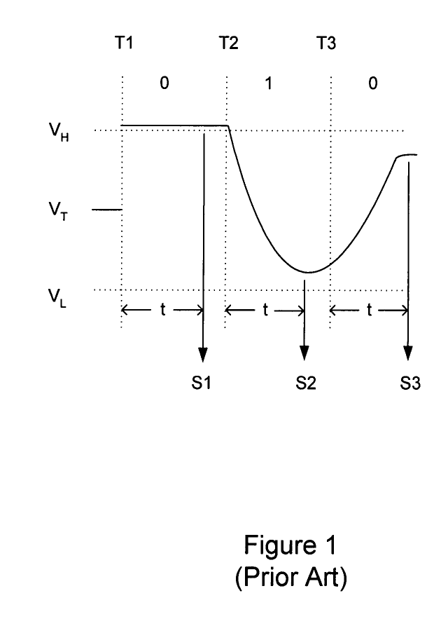

FIG. 2 illustrates a prior-art output driver.

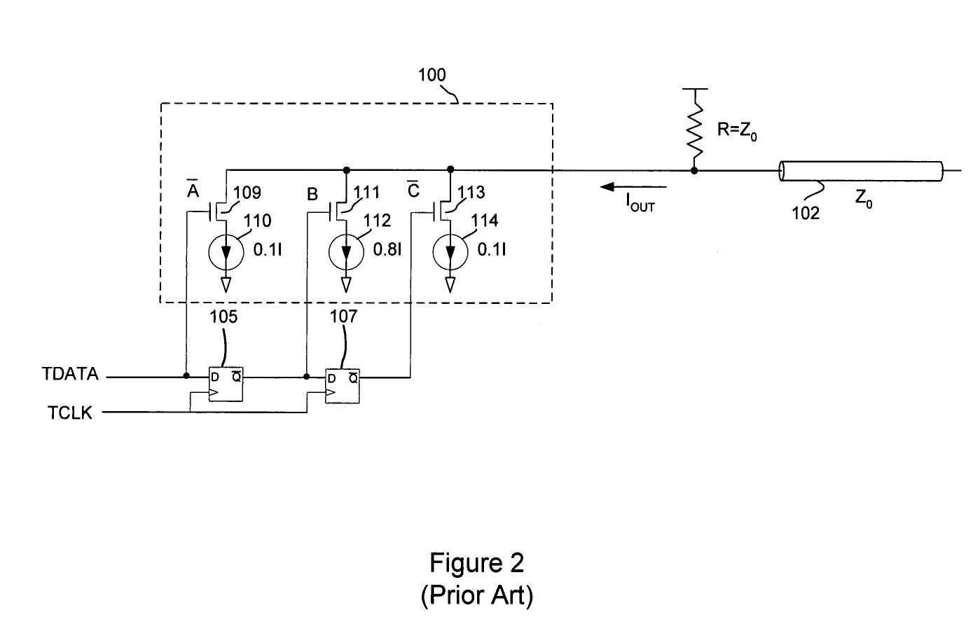

FIG. 3 illustrates the effect of the future, present, and past data values on the total current drawn by the prior-art output driver of FIG. 2.

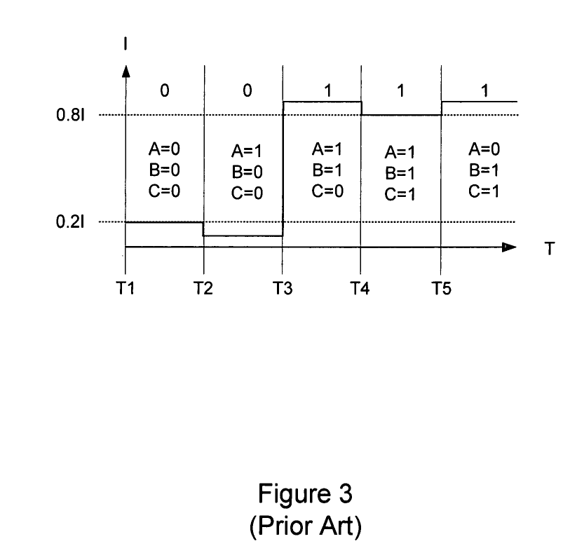

FIG. 4A illustrates an equalizing driver circuit in accordance with an embodiment of the present disclosure.

FIG. 4B illustrates an exemplary more detailed view of the equalizing driver circuit of FIG. 4A in accordance with an embodiment of the present disclosure.

FIG. 5 shows a table that illustrates the operation of the equalizing driver circuit of FIG. 4B in response to exemplary values of weights, W_{A}, W_{B}, and W_{C}, in accordance with an embodiment of the present disclosure.

FIG. 6 shows an exemplary embodiment of an allocation and dedication logic circuit that may be used to implement the allocation and dedication logic of FIG. 4B in accordance with an embodiment of the present disclosure.

FIG. 7 shows a table that illustrates a decoding operation performed within the coding circuits of the allocation and dedication logic circuit of FIG. 6 in accordance with an embodiment of the present disclosure.

FIG. 8 shows a table that illustrates a shift operation performed within the shift circuit of the allocation and dedication logic circuit of FIG. 6 in accordance with an embodiment of the present disclosure.

FIG. 9 shows a table that illustrates a logic operation performed within the select logic circuit of the allocation and dedication logic circuit of FIG. 6 in accordance with an embodiment of the present disclosure.

FIG. 10 shows an exemplary embodiment of a select logic circuit that may be used to implement the select logic circuits of FIG. 6 that operates in accordance with the table 900 of FIG. 9 in accordance with an embodiment of the present disclosure.

FIG. 11 shows a table that illustrates a logic operation performed within the DC and DON control signal logic circuits of FIG. 6 in accordance with an embodiment of the present disclosure.

FIG. 12 shows an exemplary embodiment of a keeper circuit that may be used to implement the keeper circuits of FIG. 4B in accordance with an embodiment of the present disclosure.

FIG. 13 shows an exemplary embodiment of an adjustable current source that may be used to implement the adjustable current sources within the dedicated data sub-driver circuit, dedicated pre-tap sub-driver circuit, and dedicated post-tap sub-driver circuit of FIG. 4B in accordance with an embodiment of the present disclosure.

FIG. 14A shows a timing diagram illustrating the signal timing for when an additional current path provided by a keeper circuit is switched on in the allocated driver circuitry of FIG. 4B in accordance with an embodiment of the present disclosure.

FIG. 14B shows a timing diagram illustrating the signal timing for when an additional current path provided by a keeper circuit is switched on in the dedicated driver circuitry of FIG. 4B in accordance with an embodiment of the present disclosure.

FIG. 15A shows a timing diagram illustrating the signal timing for when an additional current path provided by a keeper circuit is switched off in the allocated driver circuitry of FIG. 4B in accordance with an embodiment of the present disclosure.

FIG. 15B shows a timing diagram illustrating the signal timing for when an additional current path provided by a keeper circuit is switched off in the dedicated driver circuitry of FIG. 4B in accordance with an embodiment of the present disclosure.

FIG. 16 shows a voltage waveform diagram illustrating LSB and MSB rollover when an additional current path is provided by a keeper circuit in either the allocated driver circuitry or the dedicated driver circuitry of FIG. 4B in accordance with an embodiment of the present disclosure.

### DETAILED DESCRIPTION OF EXEMPLARY EMBODIMENT(S)

According to the present disclosure, an equalizing driver circuit is provided. In one particular exemplary embodiment, the equalizing driver circuit may comprise dedicated driver circuitry having at least one first current source switchably coupled to an output node of the driver circuit, wherein the at least one first current source is configured to selectively draw a variable quantity of current. The equalizing driver circuit may also comprise allocated driver circuitry having at least one second current source switchably coupled to the output node, wherein the at least one second current source is configured to draw a fixed quantity of current.

In accordance with other aspects of this particular exemplary embodiment, the driver circuit may further beneficially comprise logic circuitry coupled to the dedicated driver circuitry and the allocated driver circuitry, wherein the logic circuitry generates a first plurality of control signals for controlling the coupling of the at least one first current source to the output node and the coupling of the at least one second current source to the output node. If such is the case, the dedicated driver circuitry may beneficially comprise at least one keeper circuit having an output coupled to the at least one first current source, wherein the at least one keeper circuit switchably provides at least a portion of the variable quantity of current to the at least one first current source based at least in part upon a second plurality of control signals generated by the logic circuitry. Also, if such is the case, the allocated driver circuitry may beneficially comprise at least one keeper circuit having an output coupled to the at least one second current source, wherein the at least one keeper circuit switchably provides at least a portion of the fixed quantity of current to the at least one second current source based at least in part upon the second plurality of control signals generated by the logic circuitry.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

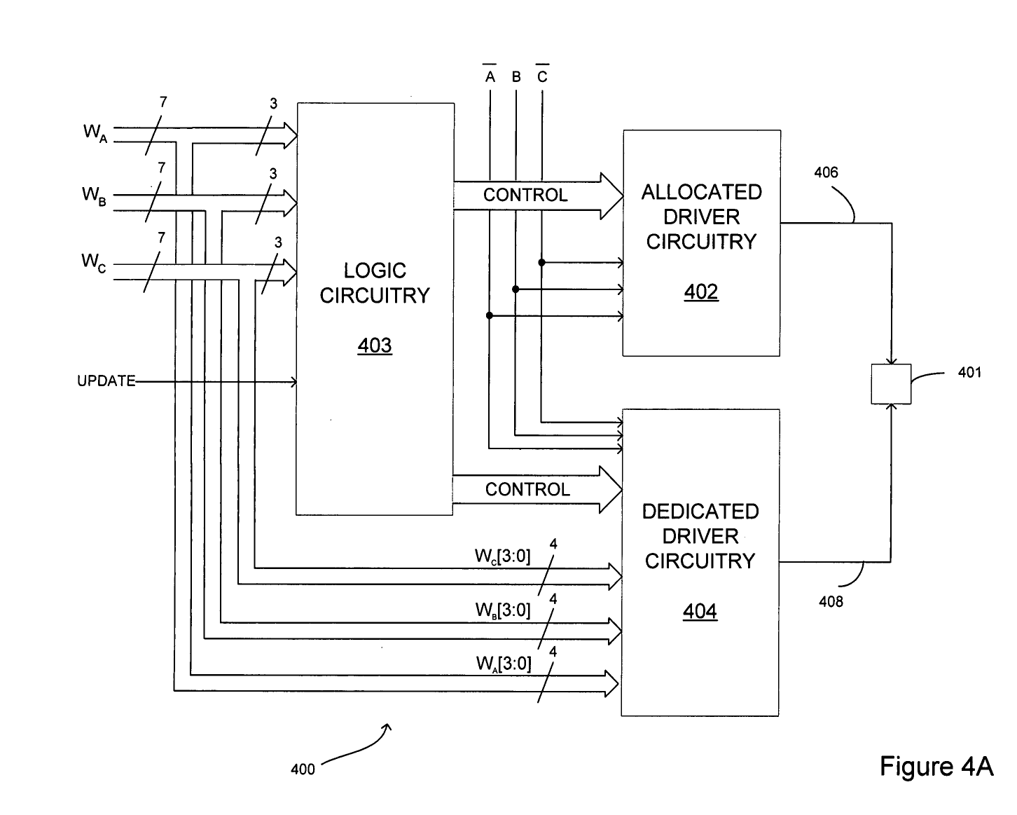

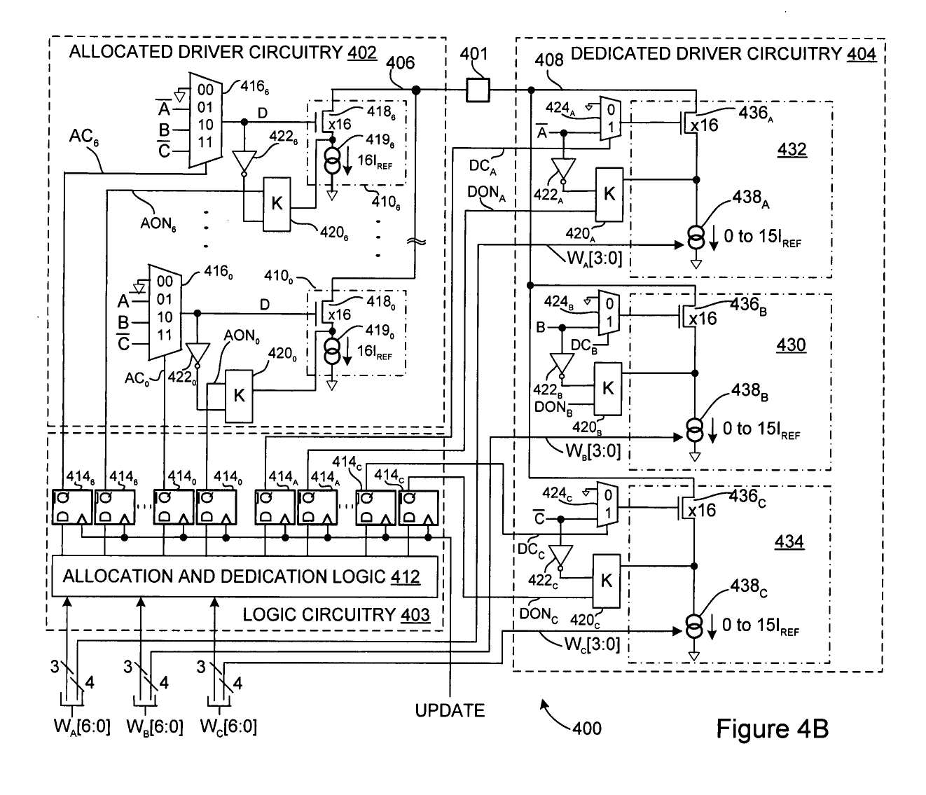

Referring to FIG. 4A, there is shown an equalizing driver circuit 400 in accordance with an embodiment of the present disclosure. The equalizing driver circuit 400 comprises allocated driver circuitry 402, dedicated driver circuitry 404, and logic circuitry 403. The equalizing driver circuit 400 receives primary data value B, and complemented pre- and post-tap data values /A and /C as inputs. The equalizing driver circuit 400 also receives weight values, W_{A}, W_{B}, and W_{C}, as inputs. The weight values represent the relative output signal contributions of primary and equalizing data values during each transmission interval, and may be provided, for example, by a configuration circuit (not shown) within an integrated circuit containing the equalizing driver circuit 400 or, alternatively, by an external source such as, for example, another integrated circuit device (not shown). In one particular exemplary embodiment, each weight value may be stored in a register and provided to the equalizing driver circuit 400 as required. Each weight value may then be updated as often as it is possible to write to the register. The equalizing driver circuit 400 additionally receives an update signal (i.e., UPDATE), the function of which will be described in detail below.

The most significant bits (MSBs) of the weight values, W_{A}, W_{B}, and W_{C}, are provided to the logic circuitry 403 which, in response thereto, generates control signals for both the allocated driver circuitry 402 and the dedicated driver circuitry 404. The least significant bits (LSBs) of the weight values, W_{A}, W_{B}, and W_{C}, are provided to the dedicated driver circuitry 404 which, in response thereto, as well as in response to control signals from the logic circuitry 403 and the primary data value B and complemented pre- and post-tap data values /A and /C, outputs a dedicated output signal to output pad 401 via signal line 408. The allocated driver circuitry 402 receives the control signals from the logic circuitry 403 and the primary data value B and complemented pre- and post-tap data values /A and /C, and, in response thereto, outputs an allocated output signal to output pad 401 via signal line 406. The combination of the dedicated output signal from the dedicated driver circuitry 404 and the allocated output signal from the allocated driver circuitry 402 forms an equalized output signal on output pad 401.

In the exemplary embodiment of FIG. 4A, each of the weight values, W_{A}, W_{B}, and W_{C}, are 7-bit values, the most significant three bits of which are provided to the logic circuitry 403 and the least four significant bits of which are provided to the dedicated driver circuitry 404. The weight values may comprise more or fewer bits in alternative embodiments, and the distribution of the constituent bits of the weight values between the allocated and dedicated driver circuits may be different.

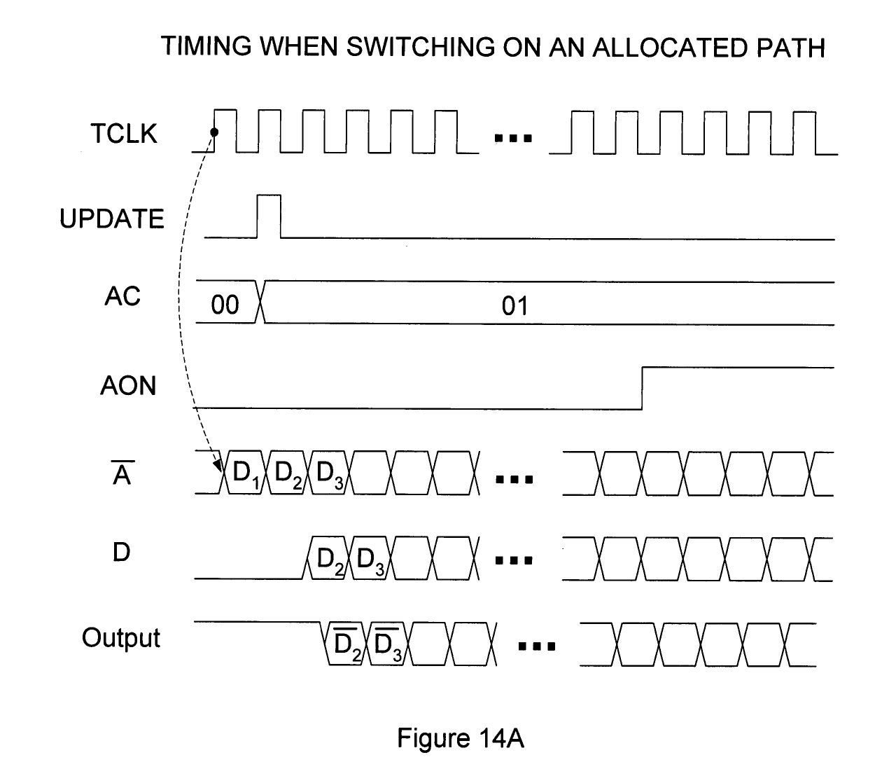

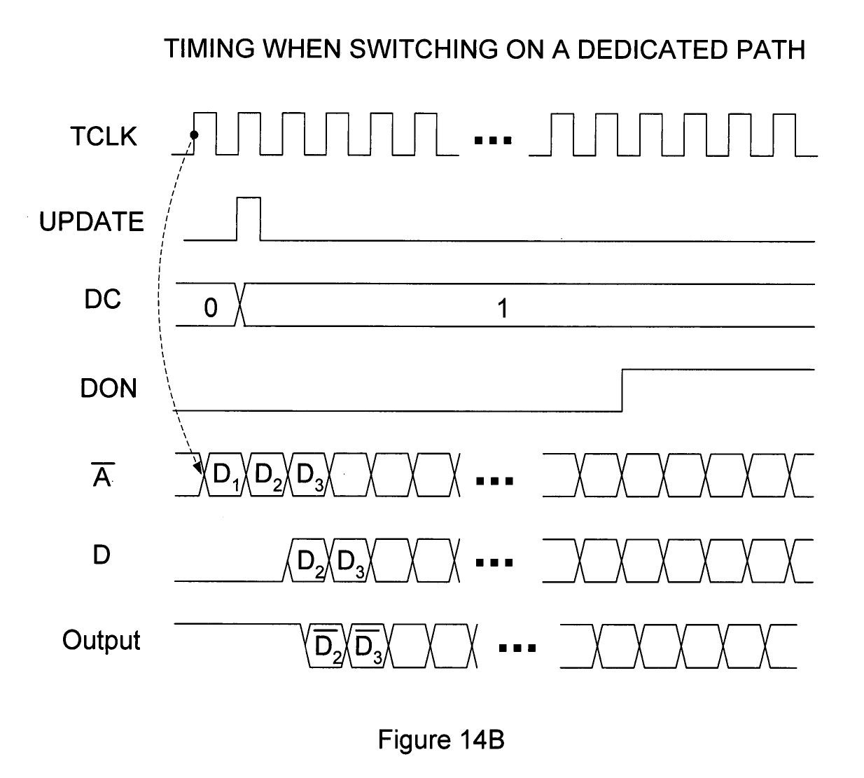

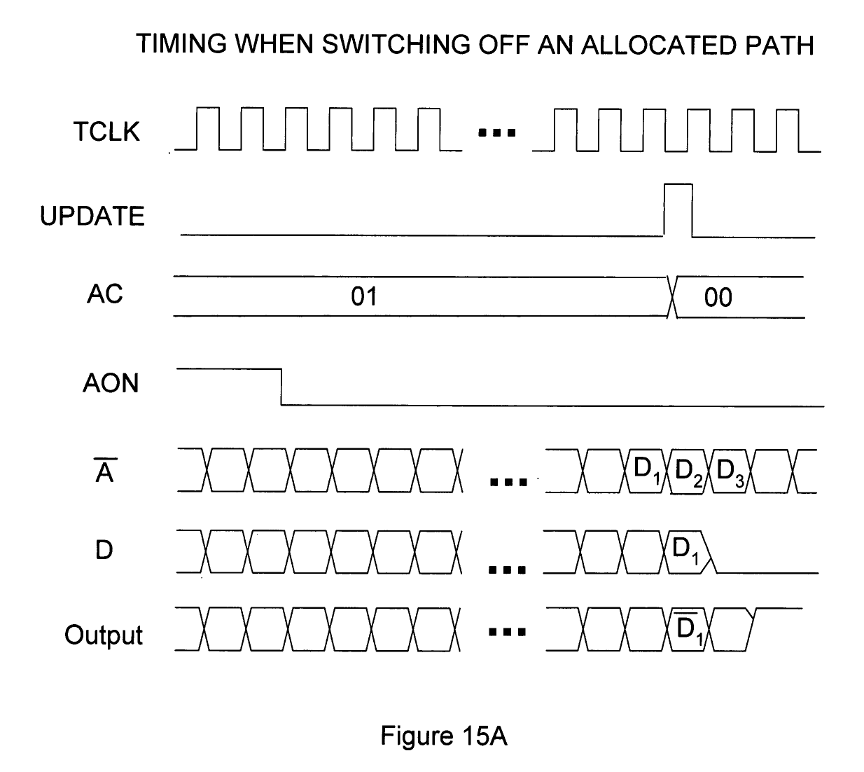

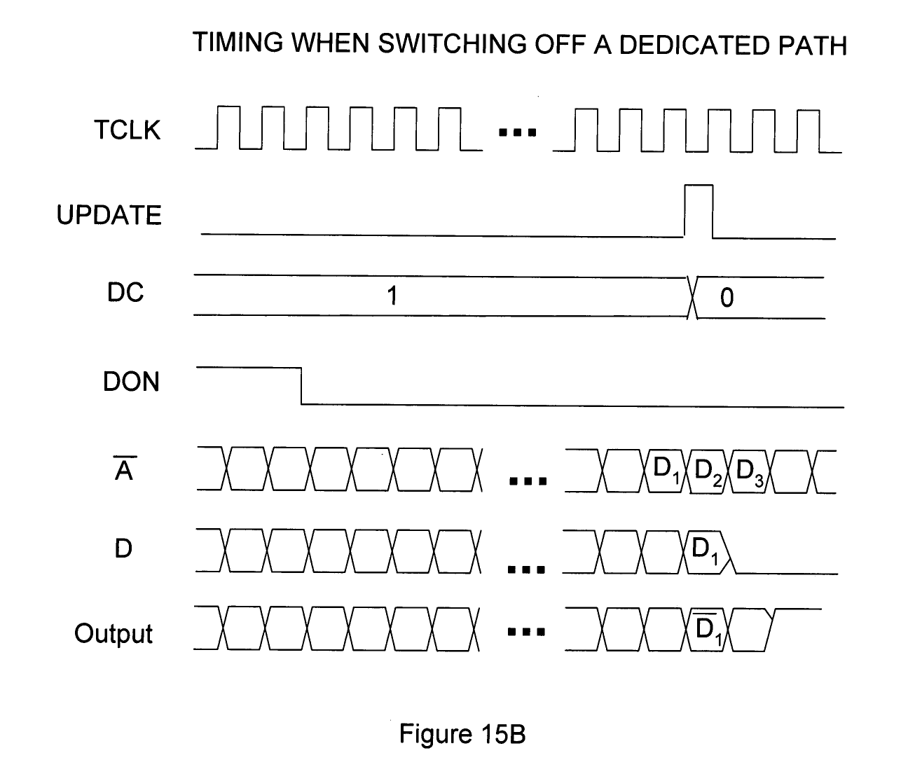

Referring to FIG. 4B, there is shown an exemplary more detailed view of the equalizing driver circuit 400 of FIG. 4A in accordance with an embodiment of the present disclosure. The logic circuitry 403 comprises allocation and dedication logic 412 which is responsive to the weight values, W_{A}, W_{B}, and W_{C}, by generating an allocation control signal, AC, as well as a corresponding additional allocated driver circuitry current path enable signal, AON, both of which are multi-bit signals in this particular exemplary embodiment although the present disclosure is not limited in this regard as discussed below. The allocation and dedication logic 412 is also responsive to the weight values, W_{A}, W_{B}, and W_{C}, by generating a dedication control signal, DC, as well as a corresponding additional dedicated driver circuitry current path enable signal, DON, both of which are multi-bit signals in this particular exemplary embodiment although the present disclosure is not limited in this regard as discussed below. The logic circuitry 403 also comprises a plurality of latches 414 for synchronously latching a respective plurality of bits from the allocation control signal, AC, the additional allocated driver circuitry current path enable signal, AON, the dedication control signal, DC, and the additional dedicated driver circuitry current path enable signal, DON. The plurality of latches 414 is clocked by the update signal (i.e., UPDATE), which may be generated within an integrated circuit containing the equalizing driver circuit 400 or, alternatively, by an external source such as, for example, another integrated circuit device (not shown). In some embodiments, the update signal (i.e., UPDATE) may be derived from a transmit clock signal (TCLK) so as to synchronize the handoff of data (whether it be for equalization or otherwise) between outputs that are turning on and those that are turning off to the transmit clock signal (TCLK), and thereby assist in removing output glitching due to signal overlap. See, for example, FIGS. 14A, 14B, 15A, and 15B.

In the embodiment of FIG. 4B, the allocation control signal, AC, is a fourteen-bit signal (more or fewer bits may be used in alternative embodiments) in which respective groups of two bits are used to select inputs of multiplexers 416₀-416₆ in the allocated driver circuitry 402. That is, allocation control bit pair AC₀[1:0] is coupled to the select input of multiplexer 416₀, allocation control bit pair AC₁[1:0] (not shown) is coupled to the select input of multiplexer 416₁ (not shown), and so forth to allocation control bit pair AC₆[1:0] which is coupled to the select input of multiplexer 416₆. In the embodiment of FIG. 4B, each of the multiplexers 416 comprises four input ports (designated ‘00’, ‘01’, ‘10’ and ‘11’ in FIG. 4B) coupled respectively to receive an ‘OFF’ signal (e.g., ground), a complemented pre-tap data value (/A), a primary data value (B), and a complemented post-tap data value (/C).

At this point it should be noted that in accordance with other embodiments of the present disclosure, the /A, B, and /C inputs to the multiplexers 416 may be signals derived from different sources (i.e., not all derived from the same data signal). Also, the allocation control signals, AC, as well as the dedication control signals, DC, and the driver circuitry current path enable signals, AON and DON, may be generated by circuitry other than the logic circuitry 403, such as, for example, a programmable controller.

In addition to multiplexers 416, the allocated driver circuitry 402 also comprises a corresponding plurality of sub-driver circuits 410₀-410₆. Each of the plurality of sub-driver circuits 410₀-410₆ comprises a switching transistor (418₀-418₆, respectively) having a gate terminal coupled to the output of a respective one of the multiplexers 416₀-416₆, and a current source (419₀-419₆, respectively) biased to draw current, 16I_{REF}, wherein I_{REF} is a reference current. By this arrangement, each of the sub-driver circuits 410 may be selectively controlled by an ‘OFF’ signal (e.g., ground), a complemented pre-tap data value (/A), a primary data value (B), or a complemented post-tap data value (/C). Each sub-driver circuit 410 selected to be controlled by a complemented pre-tap data value is referred to as a pre-tap sub-driver circuit and is said to be allocated to a pre-tap pool (the pre-tap pool including one or more pre-tap sub-driver circuits). Similarly, each sub-driver circuit 410 selected to be controlled by a complemented post-tap data value is referred to as a post-tap sub-driver circuit and is said to be allocated to a post-tap pool, and each sub-driver circuit 410 selected to be controlled by a primary data value is referred to as a primary data sub-driver circuit and is said to be allocated to a primary data pool. Thus, each of the sub-driver circuits 410 within the allocated driver circuitry 402 may be allocated to a pre-tap, post-tap, or primary data pool, with the allocation in a given application being determined by the allocation control signal, AC, and therefore by the most significant bits of the weight values, W_{A}, W_{B}, and W_{C}. That is, the allocated driver circuitry 402 allocates sub-driver circuits 410 that are not needed for equalization purposes to be used as data sub-drivers (and vice-versa), thereby lowering the overall number of sub-driver circuits 410 that would be necessary to achieve the same range of data and equalizing drive strengths in the absence of such sub-driver allocation. This results in a reduced number of sub-driver circuits 410 coupled to the output pad 401 (i.e., via signal path 406) which results in a corresponding beneficial reduction in parasitic capacitance of the equalizing driver circuit 400.

Of course, all of the sub-driver circuits 410 are not required to be allocated for use as a data sub-driver or for equalization purposes. For example, any unallocated sub-driver circuit 410 (i.e., sub-driver not utilized within the pre-tap, post-tap, or primary data pools) may be disabled by selection of the logic low signal (e.g., ground) input to port ‘00’ of the corresponding multiplexer 416. The current source 419 within each unallocated sub-driver circuit 410 may also be disabled. However, disabling and enabling one or more of the sub-driver circuits 410, including the respective current sources 419, can potentially cause timing/voltage noise resulting in bit errors in data being transmitted. To prevent, or at least alleviate, this noise, the allocated driver circuitry 402 may further comprise, and in the embodiment of FIG. 4B does further comprise, a plurality of keeper circuits 420₀-420₆, which operate to provide additional current paths for the current sources 419₀-419₆ in the sub-driver circuits 410₀-410₆. That is, keeper circuits 420₀-420₆ operate in conjunction with the allocation and dedication logic 412, latches 414₀-414₆, and multiplexers 416₀-416₆, respectively, to provide an additional current path for the current source 419 in each sub-driver circuit 410.

In the embodiment of FIG. 4B, the additional allocated driver circuitry current path enable signal, AON, is a seven-bit signal (more or fewer bits may be used in alternative embodiments) from which individual bits are coupled to respective inputs of keeper circuits 420₀-420₆. That is, additional allocated driver circuitry current path enable signal, AON₀, is coupled to an input of keeper circuit 420₀, additional allocated driver circuitry current path enable signal, AON₁ (not shown), is coupled to an input of keeper circuit 420₁ (not shown), and so forth to additional allocated driver circuitry current path enable signal, AON₆, which is coupled to an input of keeper circuit 420₆. In the embodiment of FIG. 4B, each of the keeper circuits 420₀-420₆ also has an input coupled to the output of a respective one of the multiplexers 416₀-416₆, through a respective inverter 422₀-422₆. By this arrangement, each of the keeper circuits 420₀-420₆ may be selectively controlled by an ‘OFF’ signal (e.g., ground), a complemented pre-tap data value (/A), a primary data value (B), or a complemented post-tap data value (/C), in addition to a respective bit of the additional allocated driver circuitry current path enable signal, AON. Each of the keeper circuits 420₀-420₆ selected to be controlled by a pre-tap data value is referred to as a pre-tap keeper circuit and is said to be allocated to a pre-tap pool (the pre-tap pool including one or more pre-tap keeper circuits). Similarly, each of the keeper circuits 420₀-420₆ selected to be controlled by a post-tap data value is referred to as a post-tap keeper circuit and is said to be allocated to a post-tap pool, and each of the keeper circuits 420₀-420₆ selected to be controlled by a primary data value is referred to as a primary data keeper circuit and is said to be allocated to a primary data pool. Thus, in the embodiment of FIG. 4B, each of the keeper circuits 420₀-420₆ within the allocated driver circuitry 402 may be allocated to a pre-tap, post-tap, or primary data pool, with the allocation in a given application being determined by the allocation control signal, AC, and the additional allocated driver circuitry current path enable signal, AON, and therefore by the most significant bits of the weight values, W_{A}, W_{B}, and W_{C}.

At this point it should be noted that, although FIG. 4B shows only a single pre-tap data value (i.e., /A) and a single post-tap data value (i.e., /C) being used, it is within the scope of the present disclosure to use additional pre-tap data values and post-tap data values.

In the embodiment of FIG. 4B, the dedicated driver circuitry 404 comprises a dedicated data sub-driver circuit 430, dedicated pre-tap sub-driver circuit 432, and dedicated post-tap sub-driver circuit 434, each comprising switching transistors 436 and adjustable current sources 438. In the embodiment of FIG. 4B, the dedicated data sub-driver circuit 430, dedicated pre-tap sub-driver circuit 432, and dedicated post-tap sub-driver circuit 434 are not scaled (i.e., the switching transistors 436 and adjustable current sources 438 in the dedicated data sub-driver circuit 430, dedicated pre-tap sub-driver circuit 432, and dedicated post-tap sub-driver circuit 434 all have the same current sinking capability). Also, the switching transistors 436 within the dedicated data sub-driver circuit 430, dedicated pre-tap sub-driver circuit 432, and dedicated post-tap sub-driver circuit 434 each have substantially the same width-length ratio as the switching transistors 418 within the sub-driver circuits 410 of the allocated driver circuitry 402 (e.g., ×16 transistors). By this arrangement, all the transistors coupled to output pad 401 within the equalizing driver circuit 400 have substantially the same size, thereby avoiding the distortion that may occur when differently sized transistors are used.

In the embodiment of FIG. 4B, the adjustable current sources 438 within the dedicated data sub-driver circuit 430, dedicated pre-tap sub-driver circuit 432, and dedicated post-tap sub-driver circuit 434 are adjustable from 0 to 15I_{REF}. Accordingly, a bias current ranging from 0 to 15I_{REF} in steps of I_{REF} may be selected within the dedicated data sub-driver circuit 430, dedicated pre-tap sub-driver circuit 432, and dedicated post-tap sub-driver circuit 434 according to the LSBs of the weight values, W_{B}, W_{A} and W_{C}, respectively.

The least significant bits (LSBs) of weight values, W_{B}, W_{A}, and W_{C}, constitute bias control signals for the adjustable current sources 438 within the dedicated data sub-driver circuit 430, dedicated pre-tap sub-driver circuit 432, and dedicated post-tap sub-driver circuit 434, respectively. Thus, the adjustable current sources 438 within the dedicated data sub-driver circuit 430, dedicated pre-tap sub-driver circuit 432, and dedicated post-tap sub-driver circuit 434 may be enabled or disabled depending upon the weight values, W_{B}, W_{A}, and W_{C}. The switching transistors 436_{A}-436_{C} may also be enabled or disabled depending upon the least significant bits (LSBs) of the weight values, W_{B}, W_{A}, and W_{C}, in addition to the state of a respective one of a complemented pre-tap data value (/A), a primary data value (B), or a complemented post-tap data value (/C). That is, the dedicated driver circuitry 404 further comprises a plurality of multiplexers 424_{A}-424_{C} having outputs coupled to the gates of respective ones of the plurality of switching transistors 436_{A}-436_{C} for selectively enabling and disabling the plurality of switching transistors 436_{A}-436_{C}. Each of the plurality of multiplexers 424_{A}-424_{C} comprises two input ports (designated “0” and “1” in FIG. 4B) coupled respectively to receive an ‘OFF’ signal (e.g., ground) and a respective one of a complemented pre-tap data value (/A), a primary data value (B), or a complemented post-tap data value (/C). Each of the plurality of multiplexers 424_{A}-424_{C} also comprises a select input port coupled respectively to receive a respective bit of the dedication control signal, DC.

In the embodiment of FIG. 4B, the dedication control signal, DC, is a three-bit signal (more or fewer bits may be used in alternative embodiments) in which respective bits are coupled to select input ports of the plurality of multiplexers 424_{A}-424_{C} in the dedicated driver circuitry 404. That is, dedication control bit DC_{A} is coupled to the select input of multiplexer 424_{A}, dedication control bit DC_{B} is coupled to the select input of multiplexer 424_{B}, and dedication control bit DC_{C} is coupled to the select input of multiplexer 424_{C}. By this arrangement, each of the switching transistors 436_{A}-436_{C} may be selectively enabled or disabled depending upon the least significant bits (LSBs) of the weight values, W_{B}, W_{A}, and W_{C}, in addition to the state of a respective one of a complemented pre-tap data value (/A), a primary data value (B), or a complemented post-tap data value (/C).

Similar to the allocated driver circuitry 402, disabling and enabling switching transistors 436 and the adjustable current sources 438 within the dedicated data sub-driver circuit 430, dedicated pre-tap sub-driver circuit 432, and dedicated post-tap sub-driver circuit 434 in the dedicated driver circuitry 404 can potentially cause timing/voltage noise resulting in bit errors in data being transmitted. To prevent, or at least alleviate, this noise, the dedicated driver circuitry 404 may further comprise, and in the embodiment of FIG. 4B does further comprise, a plurality of keeper circuits 420 which operate to provide an additional current path for the adjustable current sources 438 within the dedicated data sub-driver circuit 430, dedicated pre-tap sub-driver circuit 432, and dedicated post-tap sub-driver circuit 434. That is, keeper circuits 420_{A}-420_{C} operate in conjunction with the allocation and dedication logic 412 and latches 414_{A}-414_{C} to provide an additional current path for the adjustable current sources 438_{A}-438_{C} within the dedicated data sub-driver circuit 430, dedicated pre-tap sub-driver circuit 432, and dedicated post-tap sub-driver circuit 434.

In the embodiment of FIG. 4B, the additional dedicated driver circuitry current path enable signal, DON, is a three-bit signal (more or fewer bits may be used in alternative embodiments) from which individual bits are coupled to respective inputs of keeper circuits 420_{A}-420_{C}. That is, additional dedicated driver circuitry current path enable signal, DON_{A}, is coupled to an input of keeper circuit 420_{A}, additional dedicated driver circuitry current path enable signal, DON_{B}, is coupled to an input of keeper circuit 420_{B}, and additional dedicated driver circuitry current path enable signal, DON_{C}, is coupled to an input of keeper circuit 420_{C}. In the embodiment of FIG. 4B, each of the keeper circuits 420_{A}-420_{C} also has an input coupled to a data value signal, through a respective inverter 422_{A}-422_{C}. That is, keeper circuit 420_{A} has an input coupled to pre-tap data value, /A, through inverter 422_{A}, keeper circuit 420_{B} has an input coupled to primary data value, B, through inverter 422_{B}, and keeper circuit 420_{C} has an input coupled to post-tap data value, /C, through inverter 422_{C}. By this arrangement, each of the keeper circuits 420_{A}-420_{C} may be selectively controlled by either a complemented pre-tap data value (/A), a primary data value (B), or a complemented post-tap data value (/C), in addition to a respective bit of the additional dedicated driver circuitry current path enable signal, DON. Each of the keeper circuits 420_{A}-420_{C} selected to be controlled by a pre-tap data value is referred to as a pre-tap keeper circuit and is said to be dedicated to a pre-tap pool (the pre-tap pool including one or more pre-tap keeper circuits). Similarly, each of the keeper circuits 420_{A}-420_{C} selected to be controlled by a post-tap data value is referred to as a post-tap keeper circuit and is said to be dedicated to a post-tap pool, and each of the keeper circuits 420_{A}-420_{C} selected to be controlled by a primary data value is referred to as a primary data keeper circuit and is said to be dedicated to a primary data pool. Thus, each of the keeper circuits 420_{A}-420_{C} within the dedicated driver circuitry 404 is dedicated to a pre-tap, post-tap, or primary data pool, with the dedication in a given application being determined by the additional dedicated driver circuitry current path enable signal, DON, and therefore by the most significant bits of the weight values, W_{A}, W_{B}, and W_{C}. These dedicated pre-tap, post-tap, and primary data pools are separate and distinct from the allocated pre-tap, post-tap, and primary data pools discussed above.

At this point it should be noted that, although FIG. 4B shows only a single pre-tap sub-driver circuit 432 and a single post-tap sub-driver circuit 434, it is within the scope of the present disclosure to have additional pre-tap sub-driver circuits and post-tap sub-driver circuits (and corresponding keeper circuits) in the pre-tap and post-tap pools, respectively. Also, if such is the case, additional pre-tap sub-driver circuits and post-tap sub-driver circuits may be controlled by additional pre-tap and post-tap data values.

At this point it should also be noted that, in some embodiments, the allocation control signal, AC, and the dedication control signal, DC, are not necessarily required. That is, the allocation control signal, AC, and the dedication control signal, DC, are primarily used to provide power reduction in the equalizing driver circuit 400 so as to avoid excess power consumption when not switching back and forth between the various output data levels. However, in certain cases, where power is not a concern, the allocation control signal, AC, and the dedication control signal, DC, may not be needed and the respective inputs to the keeper circuits 420 may alternatively be set to a logic low signal level (e.g., ground) such that the keeper circuits 420 are always enabled. This might be the case for multiplexed data lines where the complemented pre-tap data value (/A), the primary data value (B), and the complemented post-tap data value (/C) are not weighted time shifted versions of the same data, but rather are separate data inputs that are time multiplexed on the same line.

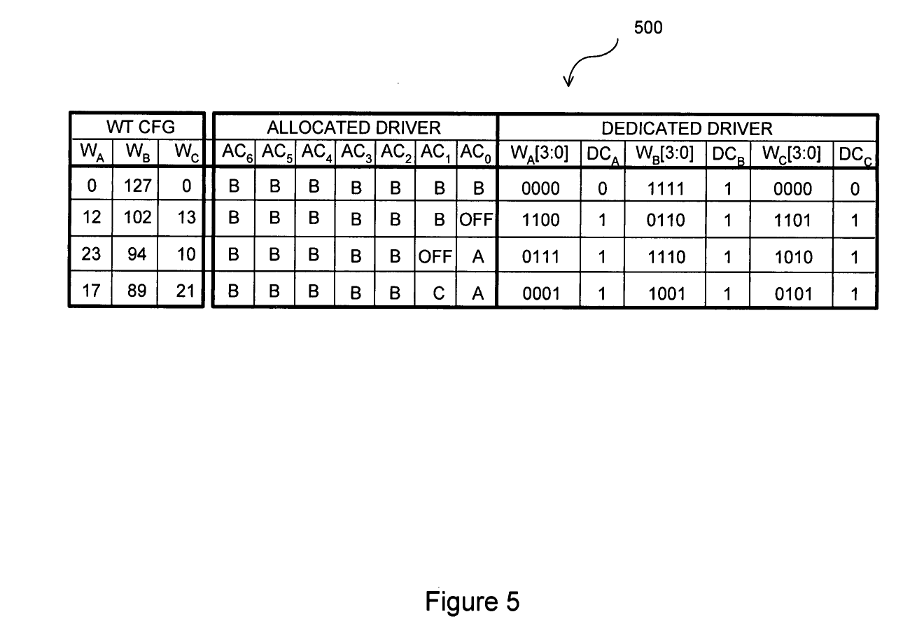

Referring to FIG. 5, there is shown a Table 500 that illustrates the operation of the equalizing driver circuit 400 of FIG. 4B in response to exemplary values of weights, W_{A}, W_{B}, and W_{C}, in accordance with an embodiment of the present disclosure. In a first example, the pre- and post-tap weights, W_{A} and W_{C}, are zero, and the data drive weight, W_{B}, is a maximum value (127×I_{REF} in this example). In this configuration, the pre- and post-tap data values do not affect the output signal generated by the equalizing driver circuit 400 and, instead, the data value, B, alone determines the output signal. To achieve the ×127 data drive strength (i.e., I_{REF}×127), the MSBs of the weight value, W_{B}, are all high to allocate all seven ×16 sub-driver circuits 410 within the allocated driver circuitry 402 to the data driver pool (illustrated in Table 500 by the selection of the data value, B, by each of the allocation control bit pairs, AC₀-AC₆, within the allocated driver circuit), and all the LSBs of the weight value, W_{B}, are high to enable the full ×15 drive strength of the dedicated data sub-driver circuit 430. Thus, a data drive strength of (7×16)+15=127×I_{REF} is achieved. None of the sub-drivers within the allocated driver circuitry 402 are allocated to the pre- or post-tap pools, and all the LSBs of the pre- and post-tap weight values are low, thereby disabling signal contributions from the dedicated pre- and post-tap sub-driver circuits 432 and 434.

The second row of Table 500 presents a second example of the operation of the equalizing driver circuit 400 in which, W_{A}=12, W_{B}=102 and W_{C}=13. Because neither of the pre- or post-tap weights is greater than 15 (i.e., greater than the maximum bias current 15I_{REF} per dedicated sub-driver), none of the sub-driver circuits 410 within the allocated driver circuitry 402 are allocated to the pre- and post-tap driver pools. Instead, the dedicated pre- and post-tap drivers are enabled to draw ×12 and ×13 currents by the setting of the pre- and post tap weight LSBs (i.e., W_{A}[3:0]=12 and W_{C}[3:0]=13). Because the specified data drive strength is less than 112 (i.e., the total data drive strength of all the unallocated sub-driver circuits 410 within the allocated driver circuitry 402), one of the sub-driver circuits 410 within the allocated driver circuitry 402 is disabled (indicated in FIG. 5 by the selection of ‘OFF’ by the allocation control bit pair, AC₀), and six sub-driver circuits 410 are allocated to the data driver pool, thereby providing a ×96 data drive strength. The dedicated data sub-driver circuit 430 is used to provide the remaining ×6 drive strength (i.e., W_{B}[3:0]=6).

Row three of Table 500 presents a third example in which W_{A}=23, W_{B}=94, and W_{C}=10. Because the pre-tap weight, W_{A}, is greater than 15, the dedicated pre-tap sub-driver circuit 432 is insufficient by itself to provide the specified drive strength. Accordingly, a ×16 sub-driver circuit 410 within the allocated driver circuitry 402 is allocated to the pre-tap driver pool (indicated in FIG. 5 by the selection of pre-tap data source ‘A’, by allocation control bit pair AC₀) to provide a ×16 pre-tap drive strength, with the remaining ×7 pre-tap drive strength being supplied by the dedicated pre-tap sub-driver circuit 432. Because the post-tap weight, W_{C}, is less than 16 (i.e., less than the bias current 16I_{REF} per allocated sub-driver), the specified post-tap drive strength is provided entirely by the dedicated post-tap sub-driver circuit 434. Finally, because the specified data drive strength is less than 6×16, but greater than 5×16, five sub-driver circuits within the allocated driver circuit are allocated to the data driver pool to provide a ×80 data drive strength, and a value of W_{B}[3:0]=14 is applied to the dedicated data sub-driver circuit 430 to provide the remaining ×14 data drive strength.

Row four of Table 500 illustrates another example of the operation of the equalizing driver circuit 400 of FIG. 4B, in this case with W_{A}=17, W_{B}=89, and W_{C}=21. In this example, one sub-driver circuit 410 within the allocated driver circuitry 402 is allocated to the pre-tap driver pool, another sub-driver circuit 410 is allocated to the post-tap driver pool and five sub-driver circuits 410 are allocated to the data driver pool, thereby providing pre-tap, post-tap, and data drive strengths of ×16, ×16 and ×80, respectively. The remaining ×1 pre-tap drive strength is supplied by the dedicated pre-tap sub-driver circuit 432; the remaining ×5 post-tap drive strength is supplied by the dedicated post-tap sub-driver circuit 434, and the remaining ×9 data drive strength is supplied by the dedicated data sub-driver circuit 430.

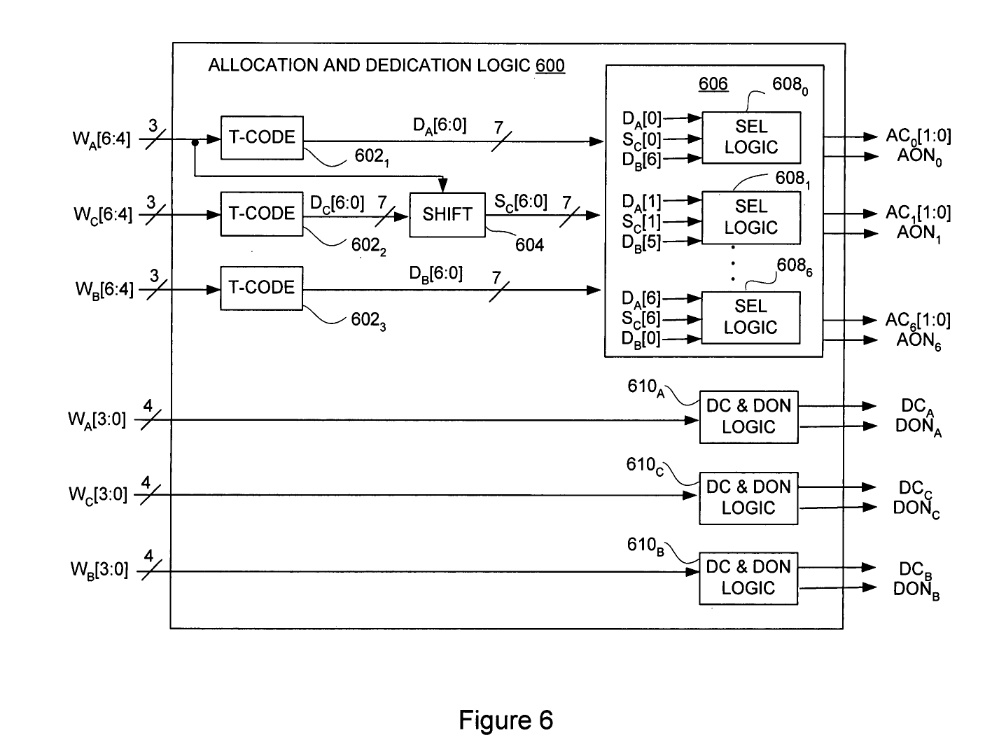

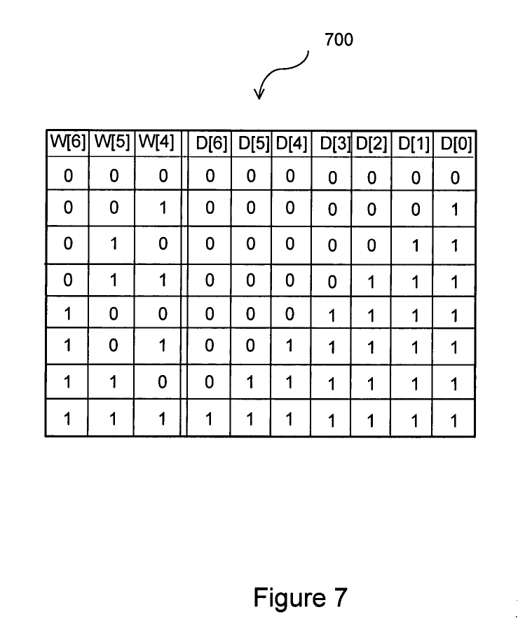

Referring to FIG. 6, there is shown an exemplary embodiment of an allocation logic circuit 600 that may be used to implement the allocation and dedication logic 412 of FIG. 4B in accordance with an embodiment of the present disclosure. The allocation logic circuit 600 comprises coding circuits 602₁, 602₂, and 602₃, a shift circuit 604, an AC and AON control signal generator 606, and DC and DON control signal logic circuits 610_{A}, 610_{B}, and 610_{C}. The coding circuits 602 receive the MSBs of the pre-tap, data, and post-tap weight values, respectively (i.e., W_{A}, W_{B}, and W_{C}), and, in response, generate decoded pre-tap, data, and post-tap values D_{A}, D_{B}, and D_{C}. In one embodiment, illustrated by Table 700 of FIG. 7, each decoded value includes 2^{N}−1 bits of which the number of logic “1” value bits corresponds to the decimal value represented by the decoded MSBs of the corresponding weight value, wherein N is the number of decoded MSBs of the corresponding weight value). Specifically, in the exemplary decoding shown by Table 700, there are three input bits (i.e., weight bits W[6:4]) and seven (2³−1) constituent bits of the decoded value, D[6:0]. When the decimal value of W[6:4] is zero (i.e., W[6:4]=000b, ‘b’ indicating binary notation), none of the decoded bits, D[6:0], is high. When the decimal value of W[6:4] is one (i.e., W[6:4]=001b), one of the decoded bits is high (bit D[0] in this example). Similarly, when the decimal value of W[6:4] is two, two of the decoded bits are high; when the decimal value of W[6:4] is three, three of the decoded bits are high; and so forth until the decimal value of W[6:4] is seven (i.e., W[6:4]=111b) in which case all seven of the decoded bits, D[6:0], are high. The coding scheme shown in FIG. 7 is referred to herein as a thermometer code and the coding circuits of FIG. 6 are referred to as thermometer coding circuits. Other coding schemes may be used in alternative embodiments.

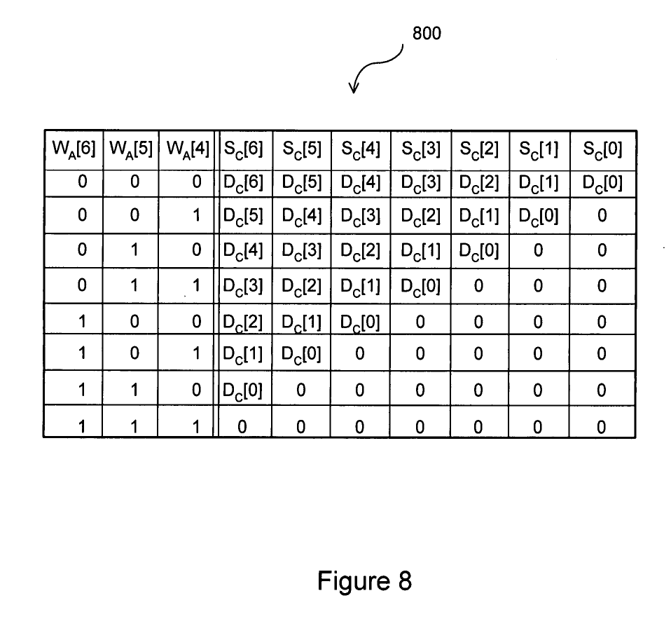

The decoded post-tap value, D_{C}, is input to the shift circuit 604, along with the MSBs of the pre-tap value (i.e., W_{A}[6:4] in this example). In one embodiment, the shift circuit 604 shifts the bit pattern of the decoded post-tap value according to the decimal value represented by the MSBs of the pre-tap value. Thus, as shown in Table 800 of FIG. 8, when the decimal value of W_{A}[6:4] is zero, the decoded post-tap value, D_{C}[6:0], is shifted left by zero bit positions to generate the shifted post-tap value, S_{C}[6:0]. When the decimal value of W_{A}[6:4] is one, the decoded post-tap value is shifted left by one bit; when the decimal value of W_{A}[6:4] is two, the decoded post-tap value is shifted left by two bits and so forth.

Referring to FIGS. 7 and 8, it can be seen that the shifting of the decoded post-tap value according to the decimal value of the pre-tap MSBs effectively aligns the decoded pre and post-tap values so that high bits within the two values do not fall within the same bit positions. That is, if the shifted post-tap value, S_{C}, is logically ORed with the decoded pre-tap value, D_{A}, the number of high bits in the resultant value will be equal to the combined number of high bits within the D_{A} and D_{C} values.

Referring again to FIG. 6, the shifted post-tap value, S_{C}, is input to the control signal generator 606 along with the decoded pre-tap value, D_{A}, and the decoded data value, D_{B}. The control signal generator 606 includes a number of select logic circuits 608₀-608₆, each of which generates a respective one of the allocation control bit pairs, AC₀[1:0]-AC₆[1:0], and a respective one of the additional allocated driver circuitry current path enable signals, AON₀-AON₆. Each select logic circuit 608 receives a respective bit of the decoded pre-tap value, D_{A}, the shifted post-tap value, S_{C}, and the data value D_{B}. In one embodiment, the connections of the constituent bits of the decoded data value, D_{B}, to the select logic circuits 608 is in reverse order relative to the bit connections of the decoded pre-tap value, D_{A}, and shifted post-tap value, S_{C}. Specifically, select logic circuit 608₀ receives bit zero of the decoded pre-tap and shifted post-tap values (i.e., bits D_{A}[0] and S_{C}[0]), but bit six of the decoded data value (i.e., D_{B}[6]). Similarly, select logic circuit 608₁ receives D_{A}[1] and S_{C}[1], but D_{B}[5]. Generally stated, in this embodiment, if there are N bits within each of the decoded and shifted values, an i^{th} one of the select logic circuits receives bits D_{A}[i], S_{C}[i], and D_{B}[(N−1)−i]. By this arrangement, any high bits within the decoded data value are effectively shifted to the leftmost positions within the overall bit field. Consequently, so long as the total number of decoded bits within values, D_{A}, D_{B}, and D_{C} is equal to or less than the number of sub-driver circuits, none of the high bits within the left-shifted decoded data value will occupy bit positions occupied by high bits within the decoded pre-tap value, D_{A}, or the shifted post-tap value, S_{C}. Note that, in alternative embodiments the same effect may be achieved by shifting the decoded data value or decoded pre-tap value instead of the post-tap value and that, similarly, the select logic connections of the decode pre- or post-tap values may be reversed instead of the decoded data value connections. In any case, the overall group of shifted, decoded values forms a control value, referred to herein as an allocation control word, that indicates the sub-driver pool (pre-tap, post-tap or data) to which sub-drivers within the allocated driver circuitry 402 are to be allocated.

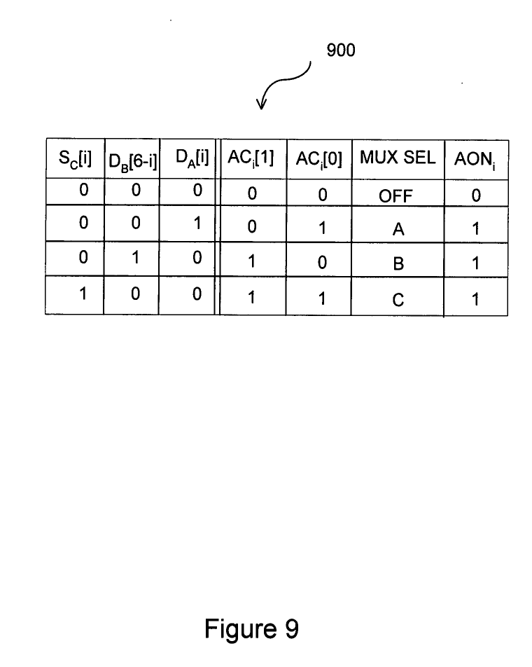

Referring to FIG. 9, there is shown a Table 900 that illustrates, by way of example, the logical operation of an i^{th} one of the select logic circuits 608₀-608₆ of FIG. 6 in accordance with an embodiment of the present disclosure. Because of the bit shifting achieved by the shift circuit 604 and the reversed bit connections of the decoded data value, D_{B}, at most one of the input values, S_{C}[i], D_{B}[6−i], and D_{A}[i] will be high for a given value of i. If none of the input values is high (as in the first row of Table 900), the two constituent bits of allocation control bit pair, ACᵢ (i.e., ACᵢ[1] and ACᵢ[0] are both low, thereby selecting the disabled condition for the corresponding sub-driver. If the decoded pre-tap bit, D_{A}[i], is high, ACi[1:0]=01 to allocate the corresponding sub-driver to the pre-tap sub-driver pool (i.e., enable the sub-driver to be controlled by the pre-tap data value). If the decoded data bit, D_{B}[6−i], is high, ACi[1:0]=10 to allocate the corresponding sub-driver to the data sub-driver pool, and if the shifted post-tap bit, S_{C}[i], is high, ACi[1:0]=11 to allocate the corresponding sub-driver to the post-tap sub-driver pool.

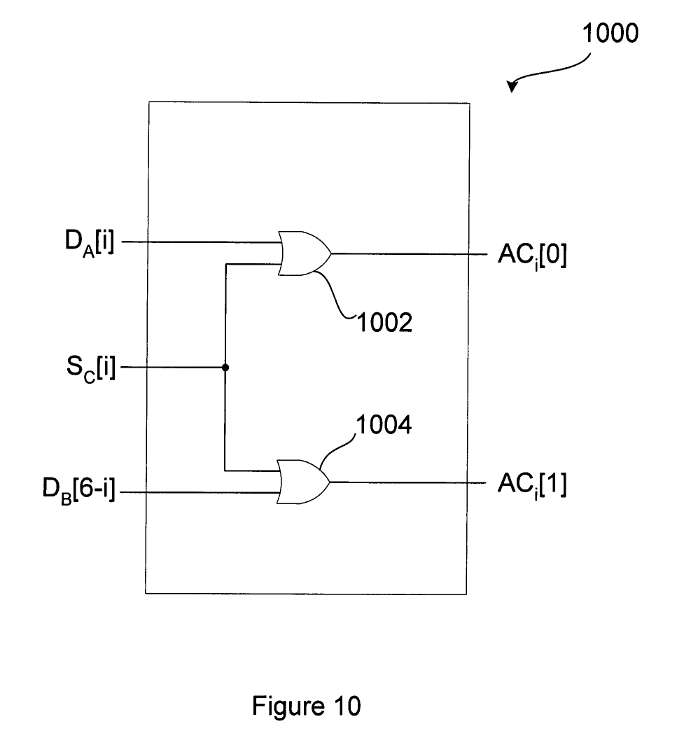

Referring to FIG. 10, there is shown an exemplary embodiment of a select logic circuit 1000 that may be used to implement the select logic circuits 608 of FIG. 6 that operates in accordance with the Table 900 of FIG. 9 in accordance with an embodiment of the present disclosure. The select logic circuit 1000 comprises a pair of logic OR gates 1002 and 1004. Logic OR gate 1002 receives a shifted post-tap bit S_{C}[i] and a decoded pre-tap bit D_{A}[i] so that ACᵢ[0] is high if either the decoded pre-tap bit or the shifted post-tap bit is high. Logic OR gate 1004 receives the shifted post-tap bit S_{C}[i] and a decoded data bit, D_{B}[6−i] so that ACᵢ[1] is high if either the decoded data bit or the shifted post-tap bit is high.

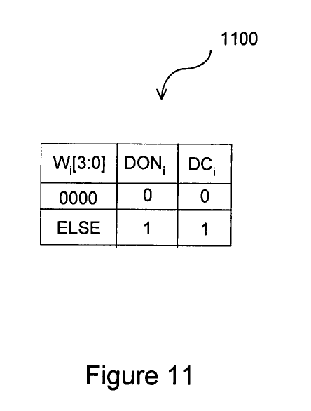

The DC and DON control signal logic circuits 610_{A}, 610_{B}, and 610_{C} receive the LSBs of the pre-tap, data, and post-tap weight values, respectively (i.e., W_{A}, W_{B}, and W_{C}), and, in response, generate the dedication control signals, DC, and the corresponding additional dedicated driver circuitry current path enable signals, DON. In one embodiment, illustrated by Table 1100 of FIG. 11, when the LSBs of the pre-tap, data, and post-tap weight values, respectively (i.e., W_{A}, W_{B}, and W_{C}), are all at logic 0 levels, the dedication control signals, DC, and the corresponding additional dedicated driver circuitry current path enable signals, DON, are also all at logic 0 levels. Otherwise, the dedication control signals, DC, and the corresponding additional dedicated driver circuitry current path enable signals, DON, are all at logic 1 levels.

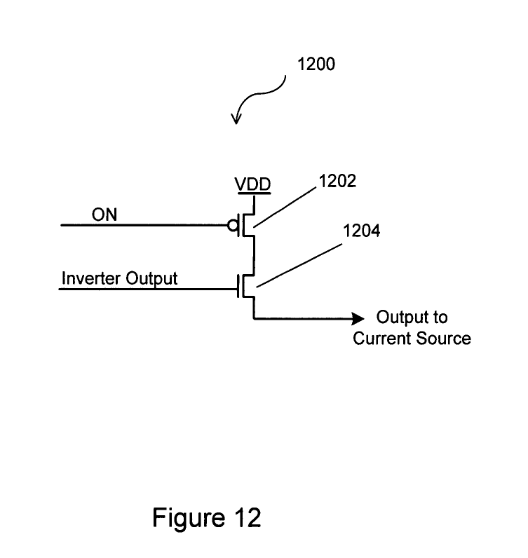

Referring to FIG. 12, there is shown an exemplary embodiment of a keeper circuit 1200 that may be used to implement the keeper circuits 420 of FIG. 4B in accordance with an embodiment of the present disclosure. The keeper circuit 1200 comprises a PMOS transistor 1202 for receiving the additional allocated driver circuitry current path enable signal, AON, in the allocated driver circuitry 402, and the additional dedicated driver circuitry current path enable signal, DON, in the dedicated driver circuitry 404. The keeper circuit 1200 also comprises an NMOS transistor 1204 for receiving the output from the inverter 422.

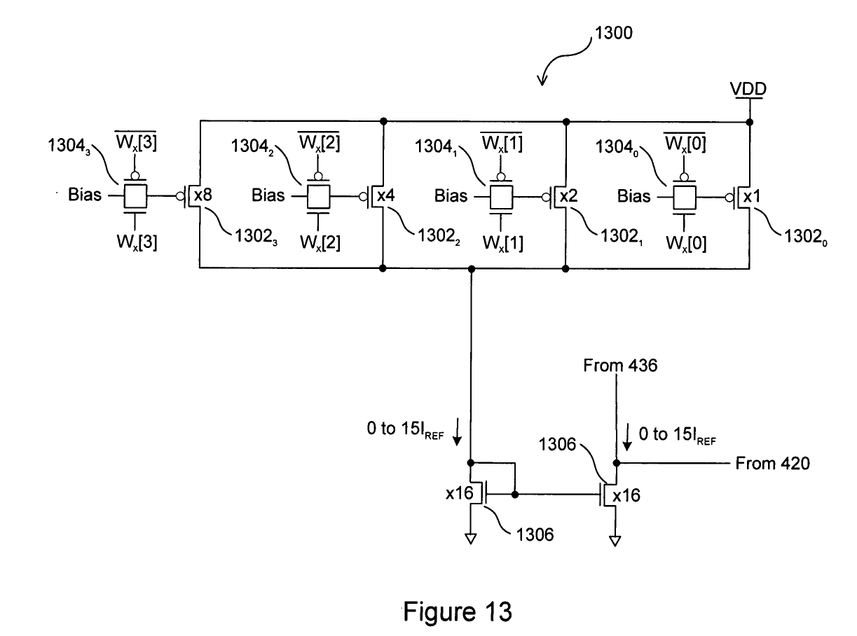

Referring to FIG. 13, there is shown an exemplary embodiment of an adjustable current source 1300 that may be used to implement the adjustable current sources 438 within the dedicated data sub-driver circuit 430, dedicated pre-tap sub-driver circuit 432, and dedicated post-tap sub-driver circuit 434 of FIG. 4B in accordance with an embodiment of the present disclosure. The adjustable current source 1300 comprises four binary weighted transistors 1302 having drive strengths (I_{REF})×1, (I_{REF})×2, (I_{REF})×4, and (I_{REF})×8, four corresponding transmission gates 1304, and a pair of current mirror transistors 1306. Each of the transmission gates 1304 is controlled by a corresponding bit of the weight value, W_{X}[3:0], for controlling the application of a bias signal (Bias) to a corresponding binary weighted transistor 1302.

Referring to FIG. 14A, there is shown a timing diagram illustrating the signal timing for when an additional current path provided by a keeper circuit 420 is switched on in an allocated driver circuitry 402 of FIG. 4B in accordance with an embodiment of the present disclosure.

Referring to FIG. 14B, there is shown a timing diagram illustrating the signal timing for when an additional current path provided by a keeper circuit 420 is switched on in a dedicated driver circuitry 404 of FIG. 4B in accordance with an embodiment of the present disclosure.

Referring to FIG. 15A, there is shown a timing diagram illustrating the signal timing for when an additional current path provided by a keeper circuit 420 is switched off in an allocated driver circuitry 402 of FIG. 4B in accordance with an embodiment of the present disclosure.

Referring to FIG. 15B, there is shown a timing diagram illustrating the signal timing for when an additional current path provided by a keeper circuit 420 is switched off in a dedicated driver circuitry 404 of FIG. 4B in accordance with an embodiment of the present disclosure.

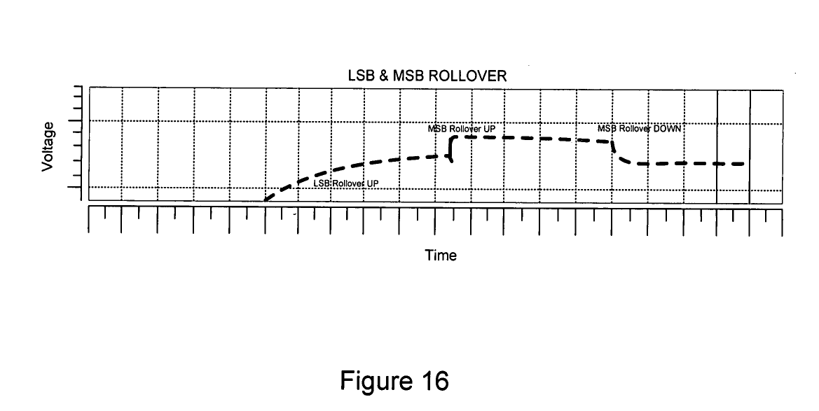

Referring to FIG. 16, there is shown a voltage waveform diagram illustrating LSB and MSB rollover when an additional current path is provided by a keeper circuit 420 in either an allocated driver circuitry 402 or a dedicated driver circuitry 404 of FIG. 4B in accordance with an embodiment of the present disclosure.

At this point it should be noted that while the equalizing driver circuit 400 of FIG. 4B has been described as enabling a specific number of sub-driver circuits to one of three driver pools, the equalizing driver circuit 400 may readily be adapted to enable allocation of any number of sub-driver circuits to any number of driver pools. In general, if there are M weight values, W₁-W_{M}, each corresponding to a different driver pool, P₁-P_{M}, to which sub-driver circuits may be allocated, then each of the weight values may be decoded to generate decoded values, D₁-D_{P}, of which values, D₂-D_{P}, may be shifted to generate a set of shifted values, S₂-S_{P}, such that none of the high bits within any of the shifted values or the decoded value, D₁, occupy the same bit positions as in another of the values. The shifting operation may be performed by any type of shifting circuit capable of performing the following general operations:
S₂=D₂ shifted according to D₁
S₃=D₃ shifted according to D₁+D₂
S₄=D₄ shifted according to D₁+D₂+D₃
. . .
S_{P}=D_{P} shifted according to D₁+D₂+ . . . +D_{P-1}
   Note that the last shift may be effected by reversing the D_{P} bit connections to the select logic circuits 608 as in the case of the decoded data bit connections in FIG. 6. Also, the shift logic may be simplified by limiting the number of shifts of any pre-tap value, post-tap value, or data value according to the maximum anticipated number of sub-drivers needed for the value. For example, one such embodiment includes one pre-tap sub-driver pool, three post-tap sub-driver pools, and one data driver pool, with a maximum of two sub-driver circuits being allocated to either of the pre- and post-tap sub-driver pools. Finally, the present disclosure is not limited to shift-based logic for allocation of sub-drivers among different sub-driver pools. In general, any combinatorial logic circuit, state-based logic circuit (e.g., state machine or processor) or other circuit for allocating sub-drivers to different driver pools may be used without departing from the spirit or scope of the present disclosure. Also, rather than allocating sub-driver circuits according to decoded weight values, decoded values themselves may be provided (e.g., from a configuration circuit or external source) to control the allocation of sub-drivers. For example, values that directly represent the state of the allocation control signals, AC, may be stored in a configuration circuit or otherwise provided to the equalizing driver circuit 400 of FIG. 4B to control the allocation of sub-drivers among different driver pools.

Although equalizing driver circuits have been described with reference to FIGS. 4-16 in terms of equalizing a data transmission to counteract the affect of ISI from signals transmitted on the same signal path, such equalizing driver circuits may additionally (or alternatively) be applied to compensate for cross-talk (e.g., inductive coupling) from signals on neighboring signal paths. For example, any of the equalizing sub-drivers disclosed herein (including allocated sub-drivers) may be controlled by a data value being transmitted on an adjacent signal path to increase or decrease the drive strength of the subject data transmission to counteract cross-talk (or other form of interference) from the adjacent signal path. Also, although equalizing driver circuits have been illustrated with single-ended signals with reference to FIGS. 4-16, it is within the scope of the present disclosure to provide equalizing driver circuits for use with differential signals. Such equalizing driver circuits may be implemented, for example, by merely coupling additional switching transistors to existing switching transistors 418 and 436 in a differential manner, with the source of each additional switching transistor coupled to a second output pad. Of course, each additional switching transistor would be driven by the complement of the signal driving each respective existing switching transistor. Also, each keeper circuit 420 would be driven by a logical NOR of the output and complemented output of multiplexers 416 in the allocated driver circuitry 402, instead of by outputs from inverters 422.

At this point it should be noted that, although the foregoing description only discussed an equalizing driver circuit 400 for receiving three data values (i.e., primary data value B, complemented pre-tap data value /A, and complemented post-tap data value /C) and three corresponding weight values (i.e., weight values W_{A}, W_{B}, and W_{C}), the present disclosure is not limited in this regard. That is, the scope of the present disclosure may encompass equalizing driver circuits having any number of switchable inputs and weight values. Also, although the foregoing description only discussed an equalizing driver circuit, the present disclosure is not limited in this regard. That is, the scope of the present disclosure may encompass not only equalizing driver circuits, but also any system requiring multiplexed data.

At this point it should be noted that, although the foregoing description only discussed an equalizing driver circuit 400 for generating an equalized output signal having only two possible states (i.e., a logic low “0” signal level or a logic high “1” signal level) on output pad 401, the present disclosure is not limited in this regard. That is, it is within the scope of the present disclosure to provide an equalizing driver circuit for generating an equalized output signal having more than two possible states (i.e., a multi-level signal). For example, an equalizing driver circuit operating in accordance with the present disclosure may generate an equalized output signal having one of four possible signal levels, thereby representing one of four possible signal values.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure can be beneficially implemented in any number of environments for any number of purposes. Accordingly, the claims set forth below should be construed in view of the full breadth and spirit of the present disclosure as described herein.

1. A driver circuit comprising:
a plurality of sub-driver circuits each having a current source switchably coupled to an output node of the driver circuit, each current source configured to draw a quantity of current; and
a plurality of keeper circuits each having an output coupled to a respective one of the plurality of sub-driver circuits, each keeper circuit switchably providing at least a portion of the quantity of current to the current source.

2. The driver circuit of claim 1, wherein each sub-driver circuit comprises a switching transistor that switchably couples the current source to the output node.

3. The driver circuit of claim 2, further comprising:
a plurality of select circuits each having an output coupled to a control input of a corresponding one of the switching transistors, each of the select circuits having a plurality of data inputs to receive a plurality of data signals and a control input to receive a respective one of a plurality of select signals, each of the select circuits being adapted to select, according to the one of the select signals, one of the plurality of data signals to be output to the control input of the corresponding one of the switching transistors.

4. The driver circuit of claim 3, further comprising:
logic circuitry having outputs coupled to the plurality of select circuits and inputs to receive a plurality of weight values that correspond, respectively, to the plurality of data signals, the logic circuitry being adapted to generate the plurality of select signals in accordance with the weight values and to output the plurality of select signals to the plurality of select circuits.

5. The driver circuit of claim 4, further comprising:
a plurality of latches that synchronously latch the plurality of select signals generated by the logic circuitry prior to being received by the plurality of select circuits.

6. The driver circuit of claim 4, wherein each of the weight values indicates a drive strength of a corresponding one of the data signals.

7. The driver circuit of claim 3, wherein the plurality of keeper circuits each comprises a pair of switching transistors, a first of the pair of switching transistors having a control input coupled to an output of a corresponding one of the plurality of select circuits for receiving one of the plurality of data signals.

8. The driver circuit of claim 7, further comprising:
a plurality of inverters that invert the plurality of data signals output from the plurality of select circuits prior to being received by the plurality of select circuits.

9. The driver circuit of claim 7, further comprising:
logic circuitry having outputs coupled to the plurality of keeper circuits and inputs to receive a plurality of weight values that correspond, respectively, to the plurality of data signals, the logic circuitry being adapted to generate a plurality of enable signals in accordance with the weight values and to output the plurality of enable signals to the plurality of keeper circuits.

10. The driver circuit of claim 9, wherein a second of the pair of switching transistors in each of the plurality of keeper circuits has a control input coupled to a corresponding one of the outputs of the logic circuitry.

11. The driver circuit of claim 9, further comprising:
a plurality of latches that synchronously latch the plurality of enable signals generated by the logic circuitry prior to being received by the plurality of keeper circuits.

12. The driver circuit of claim 9, wherein each of the weight values indicates a drive strength of a corresponding one of the data signals.

13. The driver circuit of claim 1, wherein the plurality of keeper circuits each comprises a pair of switching transistors, a first of the pair of switching transistors having a control input for receiving one of a plurality of data signals.

14. The driver circuit of claim 13, wherein at least one of the plurality of data signals corresponds to a data value transmitted by the driver circuit in a previous transmission.

15. The driver circuit of claim 13, wherein at least one of the plurality of data signals corresponds to a data value to be transmitted by the driver circuit in a subsequent transmission.

16. The driver circuit of claim 1, wherein each of the sub-driver circuits is a pull-down sub-driver circuit.

17. The driver circuit of claim 1, wherein each of the sub-driver circuits is a push-pull sub-driver circuit.

18. The driver circuit of claim 1, wherein each of the sub-driver circuits is a multilevel signaling sub-driver circuit.

19. The driver circuit of claim 1, wherein each of the sub-driver circuits is a differential sub-driver circuit.

20. A method of operation within a driver circuit, the method comprising:
switchably coupling a current source to an output node of the driver circuit, the current source configured to draw a quantity of current; and
switchably providing at least a portion of the quantity of current to the current source via a keeper circuit having an output coupled to an input of the current source.

21. The method of claim 20, further comprising:
receiving a plurality of control values, each of the plurality of control values indicating a relative drive strength to be applied to a respective one of a plurality of data signals; and
switchably coupling the current source to the output node of the driver circuit by switchably driving a control input of a sub-driver circuit with one of the plurality of data signals in response to the plurality of control values.

22. The method of claim 21, further comprising:
generating a select signal in response to the plurality of control values; and
switchably coupling, in response to the select signal, one of the plurality of data signals to the control input of the sub-driver circuit.

23. The method of claim 22, further comprising:
synchronously latching the select signal.

24. The method of claim 21, further comprising:
generating an enable signal in response to the plurality of control values; and
switchably providing, in response to the enable signal, at least the portion of the quantity of current to the current source via the keeper circuit.

25. The method of claim 24, further comprising:
synchronously latching the enable signal.

26. The method of claim 21, wherein at least one of the plurality of data signals represents a pre-tap data value.

27. The method of claim 21, wherein at least one of the plurality of data signals represents a post-tap data value.

28. The method of claim 21, wherein at least one of the plurality of data signals represents a first data value to be transmitted on a first signaling path and at least one other of the plurality of data signals represents a data value to be transmitted on a second signaling path simultaneously with the transmission of the first data value on the first signaling path.

29. A driver circuit comprising:
means for switchably coupling a current source to an output node of the driver circuit, the current source configured to draw a quantity of current; and
means for switchably providing at least a portion of the quantity of current to the current source via a keeper circuit having an output coupled to an input of the current source.

30. A driver circuit comprising:
a sub-driver circuit having a current source switchably coupled to an output node of the driver circuit, the current source configured to draw a quantity of current; and
a keeper circuit having an output coupled to the sub-driver circuit, the keeper circuit switchably providing at least a portion of the quantity of current to the current source.

31. A driver circuit comprising:
dedicated driver circuitry having a first plurality of current sources switchably coupled to an output node of the driver circuit, each of the first plurality of current sources configured to selectively draw a variable quantity of current; and
allocated driver circuitry having a second plurality of current sources switchably coupled to the output node, each of the second plurality of current sources configured to draw a fixed quantity of current.

32. The driver circuit of claim 31, further comprising:
logic circuitry coupled to the dedicated driver circuitry and the allocated driver circuitry, the logic circuitry generating a first plurality of control signals for controlling the coupling of the first plurality of current sources to the output node and the coupling of the second plurality of current sources to the output node.

33. The driver circuit of claim 32, wherein the dedicated driver circuitry comprises a plurality of keeper circuits each having an output coupled to a respective one of the first plurality of current sources, each keeper circuit switchably providing at least a portion of the variable quantity of current to a respective one of the first plurality of current sources based at least in part upon a second plurality of control signals generated by the logic circuitry.

34. The driver circuit of claim 32, wherein the allocated driver circuitry comprises a plurality of keeper circuits each having an output coupled to a respective one of the second plurality of current sources, each keeper circuit switchably providing at least a portion of the fixed quantity of current to a respective one of the second plurality of current sources based at least in part upon a second plurality of control signals generated by the logic circuitry.

35. A method of operation within a driver circuit, the method comprising:
switchably coupling a first plurality of current sources to an output node of the driver circuit, each of the first plurality of current sources configured to selectively draw a variable quantity of current; and
switchably coupling a second plurality of current sources to the output node, each of the second plurality of current sources configured to draw a fixed quantity of current.

36. A driver circuit comprising:
means for switchably coupling a first plurality of current sources to an output node of the driver circuit, each of the first plurality of current sources configured to selectively draw a variable quantity of current; and
means for switchably coupling a second plurality of current sources to the output node, each of the second plurality of current sources configured to draw a fixed quantity of current.

37. A driver circuit comprising:
dedicated driver circuitry having a first current source switchably coupled to an output node of the driver circuit, the first current source configured to selectively draw a variable quantity of current; and
allocated driver circuitry having a second current source switchably coupled to the output node, the second current source configured to draw a fixed quantity of current.

38. The driver circuit of claim 37, further comprising:
logic circuitry coupled to the dedicated driver circuitry and the allocated driver circuitry, the logic circuitry generating a first plurality of control signals for controlling the coupling of the first current source to the output node and the coupling of the second current source to the output node.

39. The driver circuit of claim 38, wherein the dedicated driver circuitry comprises a keeper circuit having an output coupled to the first current source, the keeper circuit switchably providing at least a portion of the variable quantity of current to the first current source based at least in part upon a second plurality of control signals generated by the logic circuitry.

40. The driver circuit of claim 38, wherein the allocated driver circuitry comprises a keeper circuit having an output coupled to the second current source, the keeper circuit switchably providing at least a portion of the fixed quantity of current to the second current source based at least in part upon a second plurality of control signals generated by the logic circuitry.

41. A method of operation within a driver circuit, the method comprising:
switchably coupling a first current source to an output node of the driver circuit, the first current source configured to selectively draw a variable quantity of current; and
switchably coupling a second current source to the output node, the second current source configured to draw a fixed quantity of current.

42. A driver circuit comprising:
means for switchably coupling a first current source to an output node of the driver circuit, the first current source configured to selectively draw a variable quantity of current; and
means for switchably coupling a second current source to the output node, the second current source configured to draw a fixed quantity of current.

43. A computer readable storage medium having a data file which contains a description of a driver circuit that comprises:
a plurality of sub-driver circuits each having a current source switchably coupled to an output node of the driver circuit, each current source configured to draw a quantity of current; and
a plurality of keeper circuits each having an output coupled to a respective one of the plurality of sub-driver circuits, each keeper circuit switchably providing at least a portion of the quantity of current to a respective current source.
